(19) United States
(12) Patent Application Publication
(10) Pub. No.: US 2016/0240700 A1
(43) Pub. Date: Aug. 18, 2016

(54) Solar Battery

(71) Applicant: LG INNOTEK CO., LTD., Seoul (KR)

(72) Inventor: Hee Kyung Yoon, Seoul (KR)

(21) Appl. No.: 15/028,581

(22) PCT Filed: Oct. 9, 2014
(86) PCT No.: PCT/KR2014/009494

§ 371 Date: Apr. 11, 2016

(30) Foreign Application Priority Data
Oct. 10, 2013 (KR) 10-2013-0120498

(51) Int. Cl. H01L 31/0296; H01L 31/0224

(52) U.S. Cl. CPC H01L 31/0296; H01L 31/022466; H01L 31/022475

(57) ABSTRACT

A solar battery according to an embodiment comprises: a support substrate; a rear electrode layer arranged on the support substrate; a light absorbing layer arranged on the rear electrode layer; a buffer layer arranged on the light absorbing layer; and a front electrode layer arranged on the buffer layer, wherein the buffer layer comprises Zn(O,S), and the content of sulfur (S) in the buffer layer increases towards the front electrode layer starting from the light absorbing layer

### TECHNICAL FIELD

The present disclosure relates to a solar cell.

### BACKGROUND ART

With an increase in interest in environmental issue and the depletion of natural resources, interest in a solar cell as alternative energy that has no environmental problems and high energy efficiency is increasing. Solar cells are classified into a silicon semiconductor solar cell, a compound semiconductor solar cell, a stacked solar cell, or the like, and a solar cell that includes a CIGS light absorbing layer according to the present disclosure belongs to the compound semiconductor solar cell.

Since copper indium gallium selenide (CIGS) that is an I-III-VI group compound semiconductor has a direct transition type energy band gap of 1 eV or higher, has the highest light absorption coefficient among semiconductors and is significantly stable electro-optically, it is a significantly ideal material as the light absorbing layer of a solar cell.

A CIGS based solar cell is formed in such a manner that a support substrate, a rear electrode layer, a light absorbing layer, a buffer layer, and a front electrode layer are sequentially stacked.

In this case, the buffer layer may be formed by two or more layers. That is, a high-resistor buffer layer that has high resistance may be further formed on the buffer layer. Such a high-resistor buffer layer may be formed from zinc oxide (i-ZnO) on which impurities are not doped.

However, since the buffer layer and the high-resistor buffer layer are formed by different processes, there is a limitation in that a process time increases when the buffer layers are formed.

Thus, there is a need for a buffer layer of a new structure that may form the buffer layers by a single process and replace the high-resistor buffer layer when the buffer layers are formed.

### DISCLOSURE OF THE INVENTION

### Technical Problem

Embodiments provide a solar cell that has enhanced photoelectric conversion efficiency.

### Technical Solution

In one embodiment, a solar cell includes a support substrate; a rear electrode layer arranged on the support substrate; a light absorbing layer arranged on the rear electrode layer; a buffer layer arranged on the light absorbing layer; and a front electrode layer arranged on the buffer layer, wherein the buffer layer comprises oxygen doped zinc sulfide (Zn (O, S)), and content of sulfur (S) in the buffer layer varies towards the front electrode layer starting from the light absorbing layer.

### Advantageous Effects

A solar cell according to an embodiment includes a first buffer layer and a second buffer layer that are different in the content of sulfur. That is, the first buffer layer that is arranged on a light absorbing layer includes less sulfur than the second buffer layer that is arranged on the first buffer layer.

Thus, the second buffer layer may be several hundred times larger than the first buffer layer in specific resistance that depends on the content of sulfur. Thus, the second buffer layer may replace the high-resistor buffer layer typically arranged on a buffer layer.

Thus, it is possible to omit the process of forming the high-resistor buffer layer that is arranged by a separate process after the forming of the buffer layer.

Also, it is possible to generally decrease the series resistance of a solar cell according to the control of specific resistance in the buffer layer.

Thus, a solar cell according to an embodiment may have enhanced process efficiency and generally enhanced photoelectric conversion efficiency.

### BRIEF DESCRIPTION OF THE DRAWINGS

FIG. 1 is a plane view of a solar cell according to an embodiment.

FIG. 2 is a cross-sectional view of a solar cell according to an embodiment.

FIG. 3 is an enlarged view of the circle A in FIG. 2.

FIGS. 4 to 10 are diagrams for explaining a method of manufacturing a solar cell according to an embodiment.

### MODE FOR CARRYING OUT THE INVENTION

In describing embodiments, the description that layers (films), regions, patterns or structures are formed “over/on” or “under/beneath” layers (films), regions, pads or patterns includes that they are formed directly or through another layer. The phrase over/on or under/beneath each layer is described based on the accompanying drawings.

Since the thickness or size of layers (films), regions, patterns or structures in the drawings may vary for the clearness and convenience of description, it does not absolutely reflect its actual size.

In the following, an embodiment is described in detail with reference the accompanying drawings.

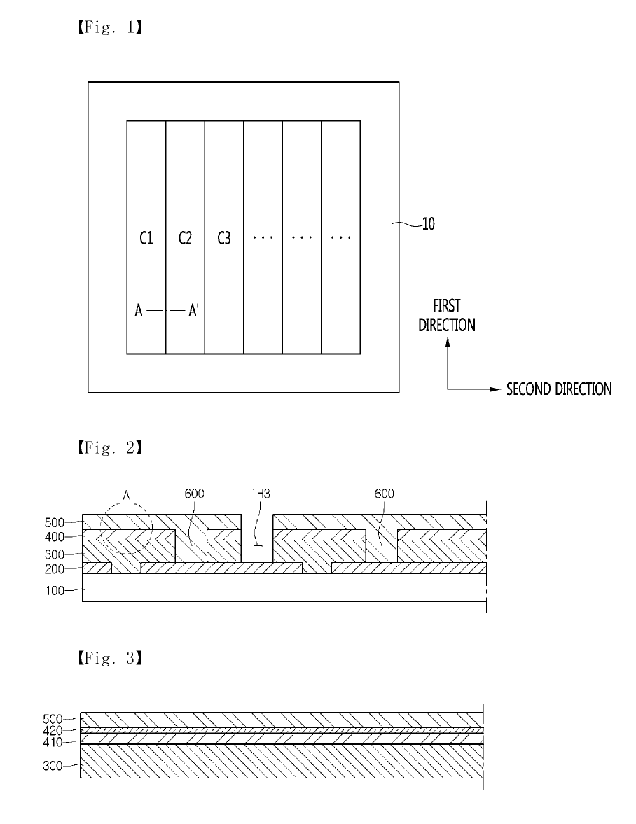

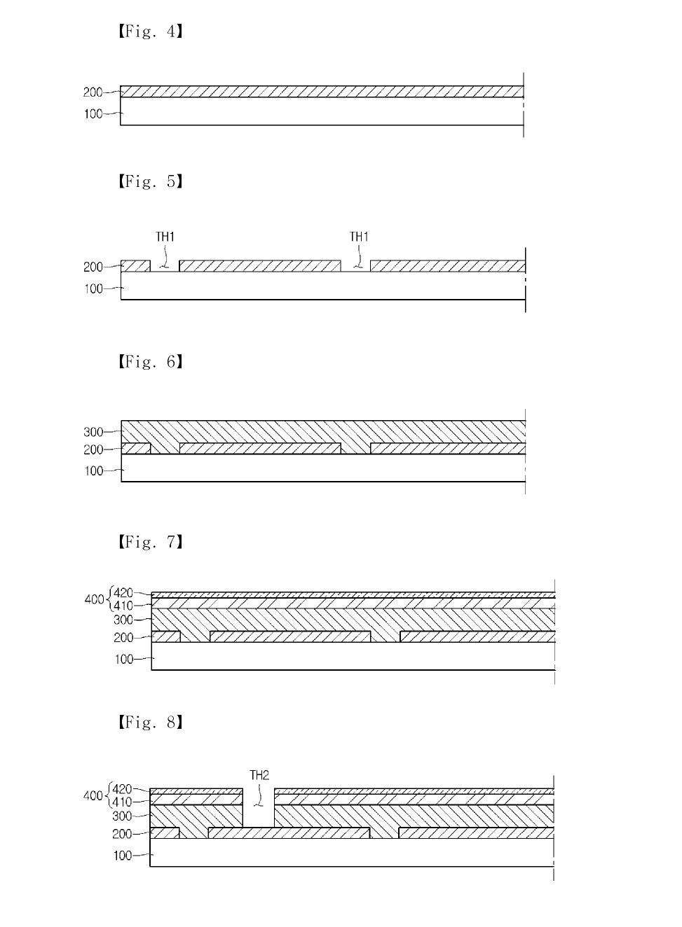

In the following, a solar cell and a manufacturing method thereof according to an embodiment are described in detail with reference to FIGS. 1 to 10. FIG. 1 is a plane view of a solar cell according to an embodiment, FIG. 2 is a cross-sectional view of a solar cell according to an embodiment, FIG. 3 is an enlarged view of the circle A in FIG. 2, and FIGS. 4 to 10 are diagrams for explaining a method of manufacturing a solar cell according to an embodiment.

Referring to FIGS. 1 to 3, a solar cell according to an embodiment includes a support substrate 100, a rear electrode layer 200, a light absorbing layer 300, a buffer layer 400, a front electrode layer 500, and a plurality of connections 600. The support substrate 100 may be an insulator. The support substrate 100 may be a glass substrate, a plastic substrate, or a metal substrate. Specifically, the support substrate 100 may be soda lime glass substrate. The support substrate 100 may be transparent. The support substrate 100 may be rigid or flexible.

The rear electrode layer 200 is arranged on the support substrate 100. The rear electrode layer 200 is a conductive layer. An example of a material used as the rear electrode layer 200 may include metal, such as molybdenum (Mo).

Also, the rear electrode layer 200 may include two or more layers. In this case, the layers may be formed from the same metal or from different metal.

First through holes TH1 are formed in the rear electrode layer 200. The first through holes TH1 are open regions that expose the top surface of the support substrate 100. The first through holes TH1 may have a shape extended in the first direction when viewed from the top.

The width of the first through holes TH1 may be about 80 μm to about 200 μm.

The rear electrode layer 200 is divided into a plurality of rear electrodes by the first through holes TH1. That is, the rear electrodes are defined by the first through holes TH1.

The rear electrodes are spaced apart by the first through holes TH1. The rear electrodes are arranged in the form of stripe.

Alternately, the rear electrodes may be arranged in the form of a matrix. In this case, the first through holes TH1 may be formed in the form of a grid when viewed form the top.

The light absorbing layer 300 is arranged on the rear electrode layer 200. Also, a material included in the light absorbing layer 300 fills the first through holes TH1.

The light absorbing layer 300 includes I-III-VI group based compound. For example, the light absorbing layer 300 may have a copper-indium-gallium-selenide (Cu (In, Ga) Se₂; CIGS) based crystal structure, copper-indium-selenide or copper-gallium-selenide based crystal structure.

In this case, the ratio of copper/III group elements may be about 0.8 to about 0.9, and the ratio of gallium/III group elements may be about 0.38 to about 0.40.

The energy band gap of the light absorbing layer 300 may be about 1 eV to about 1.8 eV.

The buffer layer 400 is arranged on the light absorbing layer 300. The buffer layer 400 is in direct contact with the light absorbing layer 300.

The buffer layer 400 may include sulfur (S). Specifically, the buffer layer 400 may include oxygen doped zinc sulfide (Zn (O, S)).

The buffer layer 400 may vary in the content of sulfur depending on the position. As an example, the buffer layer 400 may increase in the content of sulfur towards the front electrode layer starting from the light absorbing layer.

As shown in FIG. 3, the buffer layer 400 may include a first buffer layer 410 and a second buffer layer 420. Specifically, the buffer layer 400 may include the first buffer layer that is arranged on the light absorbing layer 300, and the second buffer layer 420 that is arranged on the first buffer layer 410.

The first buffer layer 410 and the second buffer layer 420 may include the same or similar material. As an example, the first buffer layer 410 and the second buffer layer 420 may include oxygen doped zinc sulfide (Zn (O, S)).

The first buffer layer 410 and the second buffer layer 420 may have different composition. Specifically, the first buffer layer 410 and the second buffer layer 420 may be different in the content of sulfur that is included in Zn (O, S).

Specifically, the second buffer layer 420 may include less sulfur than the first buffer layer 410. As an example, the first buffer layer 410 may include about 10 wt % to about 15 wt % sulfur in Zn (O, S). Also, the second buffer layer 420 may include about 20 wt % to about 25 wt % sulfur in Zn (O, S).

Also, the first buffer layer 410 and the second buffer layer 420 may have different thicknesses. Specifically, the first buffer layer 410 may be formed in a larger thickness than the second buffer layer 420. As an example, the first buffer layer 410 may be formed in a thickness of about 20 nm to about 30 nm. Also, the second buffer layer 420 may be formed in a thickness of about 10 nm to about 20 nm. Also, the total thickness of the buffer layer 400, i.e., the first buffer layer 410 and the second buffer layer may be about 30 nm to about 50 nm.

In the case where the first buffer layer 410 and the second buffer layer 420 is out of the range of wt % of sulfur and the range of thickness, the difference between their specific resistances may not be equal to or larger than a desired value. Also, the second buffer layer 420 may not properly function as an insulator.

The first buffer layer 410 and the second buffer layer 420 may have band gaps of about 2.7 eV to about 2.8 eV.

The first buffer layer 410 and the second buffer layer 420 may have different specific resistances. Specifically, the specific resistance of the second buffer layer may be larger than the specific resistance of the first buffer layer. As an example, the specific resistance of the first buffer layer 410 may be smaller than or equal to about 10⁻³Ω. Also, the specific resistance of the second buffer layer 420 may be equal to or larger than about 10⁻²Ω.

The specific resistances of the buffer layers may vary according to the content of sulfur in Zn (O, S) that is included in the buffer layers. That is, the specific resistance of the buffer may increase with an increase in the content of sulfur.

That is, the second buffer layer may include more sulfur than the first buffer layer and thus the specific resistance of the second buffer layer may be larger than that of the first buffer layer.

Especially, the second buffer layer may function as an insulator according to an increase in specific resistance. Thus, it is possible to omit the forming of a high-resistor buffer layer that is typically arranged on a buffer layer.

That is, after the forming of the buffer layer, the high-resistor buffer layer that functions as an insulator has been further arranged on the buffer layer, typically. As an example, zinc oxide (i-ZnO) on which impurities are not doped is further formed.

However, a solar cell according to an embodiment may increase the content of sulfur in forming the second buffer layer to increase specific resistance so that the second buffer layer may replace the typical high-resistor buffer layer.

Thus, since it is possible to omit the process of forming the high-resistor buffer layer, it is possible to enhance process efficiency due to the reduction in process time.

Also, a solar cell according to an embodiment may regulate the content of sulfur in forming the buffer layer to form the first buffer layer having less sulfur, i.e., smaller specific resistance and then form the second buffer layer having more sulfur, i.e., larger specific resistance so that it is possible to control specific resistance in the buffer layer. Thus, it is possible to generally decrease the series resistance Rs of a solar cell.

Thus, a solar cell according to an embodiment may enhance process efficiency and enhance the efficiency of a solar cell on the whole.

Second through holes TH2 may be formed in the buffer layer 400. The second through holes TH2 are open regions that expose the top surface of the support substrate 100 and the top surface of the rear electrode layer 200. The second through holes TH2 may have a shape extended in one direction when viewed from the top. The width of the second through holes TH2 may be about 80 μm to about 200 μm but is not limited thereto.

The buffer layer 400 is defined as plurality of buffer layers by the second through holes TH2.

A front electrode layer 500 is arranged on the buffer layer 400. More specifically, the front electrode layer 500 is arranged on a third buffer layer 430. The front electrode layer 500 is transparent, conductive layer. Also, the resistance of the front electrode layer 500 is higher than that of the rear electrode layer 200.

The front electrode layer 500 includes oxide. As an example, a material used as the front electrode layer 500 may include Al doped ZnC (AZO), indium zinc oxide (IZO), indium tin oxide (ITO) or the like.

The front electrode layer 500 includes connections 600 that are in the second through holes TH2.

Third through holes TH3 are formed in the buffer layer 400 and the front electrode layer 500. The third through holes TH3 may pass through a portion or whole of the buffer layer 400 and the front electrode layer 500. That is, the third through holes TH3 may expose the top surface of the rear electrode layer 200.

The third through holes TH3 are formed adjacent to the second through holes TH2. More specifically, the third through holes TH3 are arranged next to the second through holes TH2. That is, the third through holes TH3 are arranged next to the second through holes TH2 side by side when viewed from the top. The third through holes TH3 may have a shape extended in the first direction.

The third through holes TH3 pass through the front electrode layer 500. More specifically, the third through holes TH3 may pass through the light absorbing layer 300, the buffer layer 400 and/or the high-resistor buffer partially or wholly.

The front electrode layer 500 is divided into a plurality of front electrodes by the third through holes TH3. That is, the front electrodes are defined by the third through holes TH3.

The front electrodes have a shape corresponding to the rear electrodes. That is, the front electrodes are arranged in the form of stripe. Alternately, the front electrodes may be arranged in the form of a matrix.

Also, a plurality of solar cells C1, C2, . . . is defined by the third through holes TH3. More specifically, the solar batteries C1, C2, . . . are defined by the second through holes TH2 and the third through holes TH3. That is, a solar cell according to an embodiment is divided into the solar cells C1, C2, . . . by the second through holes TH2 and the third through holes TH3. Also, the solar cells C1, C2, . . . are connected to each other in the second direction that crosses the first direction. That is, a current may flow through the solar cells C1, C2, . . . in the second direction.

That is, a solar cell panel 10 includes the support substrate 100 and the solar cells C1, C2, . . . . The solar cells C1, C2, . . . are arranged on the support substrate 100 and spaced apart from one another. Also, the solar cells C1, C2, . . . are connected to each other in series by the connections 600.

The connections 600 are arranged in the second through holes TH2. The connections 600 are extended downwards from the front electrode layer 500 and connected to the rear electrode layer 200. For example, the connections 600 are extended from the front electrode of a first cell C1 and connected to the rear electrode a second cell C2.

Thus, the connections 600 connect adjacent solar cells. More specifically, the connections 600 connect the front electrode and the rear electrode that are included in each of adjacent solar cells.

The connections 600 are integrally formed with the front electrode layer 500. That is, a material used as the connection 600 is the same as a material used as the front electrode layer 500.

As described earlier, a solar cell according to an embodiment includes the first buffer layer and the second buffer layer that are different in the content of sulfur. That is, the first buffer layer that is arranged on the light absorbing layer includes less sulfur than the second buffer layer that is arranged on the first buffer layer.

Thus, the second buffer layer may be several hundred times larger than the first buffer layer in specific resistance that depends on the content of sulfur. Thus, the second buffer layer may replace the high-resistor buffer layer typically arranged on the buffer layer.

Thus, it is possible to omit the process of forming the high-resistor buffer layer that is arranged by a separate process after the forming of the buffer layer.

Also, it is possible to decrease the series resistance of a solar cell on the whole according to the control of specific resistance in the buffer layer.

Thus, a solar cell according to an embodiment may have enhanced process efficiency and enhanced photoelectric conversion efficiency on the whole.

In the following, a manufacturing method of a solar cell according to an embodiment is described with reference to FIGS. 4 to 10. FIGS. 4 to 10 are diagrams for explaining the manufacturing method of the solar cell according to an embodiment.

Firstly, referring to FIG. 4, the rear electrode layer 200 is formed on the support substrate 100.

Subsequently, referring to FIG. 5, the rear electrode layer 200 is patterned so that the first through holes TH1 are formed. Thus, a plurality of rear electrodes, a first connection electrode and a second connection electrode are arranged on the support substrate 100. The rear electrode layer 200 may be patterned by a laser beam.

The first through holes TH1 may expose the top surface of the support substrate 100 and have a width of about 80 μm to about 200 μm.

Also, it is possible to arrange an additional layer, such as a diffusion barrier between the support substrate 100 and the rear electrode layer 200, in which case the third through holes TH1 expose the top surface of the additional layer.

Subsequently, referring to FIG. 6, the light absorbing layer 300 is arranged on the rear electrode layer 200. The light absorbing layer 300 may be formed by a sputtering process or vaporization.

For example, vaporizing copper, indium, gallium and selenium simultaneously or separately to form the CIGS based light absorbing layer 300, and forming the light absorbing layer by a selenization process after forming a metal pre-cursor film are being widely used in order to form the absorbing layer 300.

To describe forming the light absorbing layer by the selenization process after forming a metal pre-cursor film, the metal pre-cursor film is formed on the rear electrode by a sputtering process that uses a copper target, an indium target, and a gallium target.

Then, the pre-cursor film is formed as the CIGS based light absorbing layer 300 by a selenization process.

Alternatively, the sputtering process and the selenization process that use the copper target, the indium target, and the gallium target may be performed simultaneously.

Alternatively, it is possible to the CIS based or CIG based light absorbing layer 300 by a sputtering process and a selenization process that use only the copper target and the indium target or use only the copper target and the gallium target.

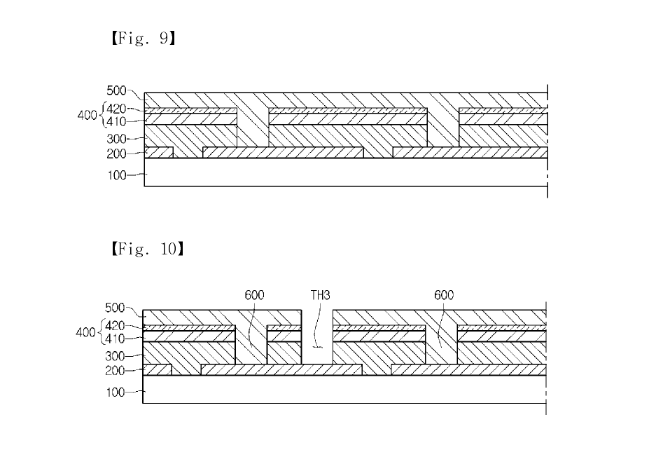

Subsequently, referring to FIG. 7, the buffer layer 400 is formed on the light absorbing layer 300. The buffer layer 400 may include the first buffer layer 410 and the second buffer layer 420, and the first buffer layer 410 and the second buffer layer 420 may be sequentially deposited.

That is, the first buffer layer 410 may be deposited on the light absorbing layer 300, and the second buffer layer 420 may be deposited on the first buffer layer 410.

As an example, the first buffer layer 410 and the second buffer layer 420 may be deposited through atomic layer deposition. However, an embodiment is not limited thereto, and the first buffer layer 410 and the second buffer layer 420 may be formed by various methods, such as chemical vapor deposition (CVD) or metal organic chemical vapor deposition (MOCVD).

In this case, the first buffer layer 410 and the second buffer layer 420 may be deposited in units of nm. Specifically, the first buffer layer 410 may be deposited in a thickness of about 20 nm to about 30 nm, and the second buffer layer 420 may be deposited in a thickness of about 10 nm to about 20 nm.

Subsequently, referring to FIG. 8, portions of the light absorbing layer 300 and the buffer layer 400 are removed so that the second through holes TH2 are formed.

The second through holes TH2 may be formed by a mechanical device, such as a tip, or a laser device.

For example, the light absorbing layer 300 and the buffer layer 400 may be patterned by a tip that has a width of about 40 μm to about 180 μm. Also, the second through holes TH2 may be formed by a laser beam that has a wavelength of about 200 nm to about 600 nm.

In this case, the width of the second through holes TH2 may be about 100 μm to about 200 μm. Also, the second through holes TH2 may expose a portion of the top surface of the rear electrode layer 200.

Subsequently, referring to FIG. 9, a transparent, conductive material is deposited on the buffer layer 400, i.e., the second buffer layer 420 to form the front electrode layer 500.

The front electrode layer 500 may be formed by the deposition of the transparent, conductive material at oxygen-free atmosphere. More specifically, the front electrode layer 500 may be formed by the deposition of Al doped zinc oxide at inert gas atmosphere that does not include oxygen.

The forming of the front electrode layer may be performed by the deposition of zinc oxide Al doped by a deposition method using a ZnO target or a reactive sputtering method using a Zn target as an RF sputtering method.

Subsequently, referring to FIG. 10, portions of the light absorbing layer 300, the buffer layer 400, and the front electrode layer 500 are removed so that the third through holes TH3 are formed. Thus, the front electrode layer 500 is patterned so that a plurality of front electrodes, a first cell C1, a second cell C2, and a third cell C3 are defined. The width of the third through holes TH3 may be about 80 μm to about 200 μm.

The characteristics, structures, and effects described in the above-described embodiments are included in at least one embodiment but are not necessarily limited to one embodiment. Furthermore, the characteristic, structure, and effect illustrated in each embodiment may be combined or modified for other embodiments by a person skilled in the art. Thus, it would be construed that contents related to such a combination and such a variation are included in the scope of embodiments.

While embodiments have been mainly described above, they are only examples and do not limit the present disclosure and a person skilled in the art to which the present disclosure pertains could appreciate that it is possible to implement many variations and applications not illustrated above without departing from the essential characteristics of the embodiments. For example, components particularly represented in the embodiments may vary. In addition, the differences related to such variations and applications should be construed as being included in the scope of the present disclosure that the following claims define.

1. A solar cell comprising:
a support substrate;
a rear electrode layer arranged on the support substrate;
a light absorbing layer arranged on the rear electrode layer;
a buffer layer arranged on the light absorbing layer; and
a front electrode layer arranged on the buffer layer,
wherein the buffer layer comprises oxygen doped zinc sulfide (Zn (O, S)), and
content of sulfur (S) in the buffer layer varies towards the front electrode layer starting from the light absorbing layer.

2. The solar cell according to claim 1, wherein the content of sulfur (S) in the buffer layer increases towards the front electrode layer starting from the light absorbing layer.

3. The solar cell according to claim 1, wherein the buffer layer is formed in a thickness of about 30 nm to about 50 nm.

4. The solar cell according to claim 1, wherein the buffer layer comprises:
a first buffer layer; and
a second buffer layer arranged on the first buffer layer,
wherein the first buffer layer and the second buffer layer are different from each other in content of sulfur.

5. The solar cell according to claim 4, wherein the second buffer layer has more sulfur than the first buffer layer.

6. The solar cell according to claim 4, wherein the first buffer layer and the second buffer layer comprises Zn (O, S), and
the first buffer layer comprises about 10 wt % to about 15 wt % sulfur in Zn (O, S).

7. The solar cell according to claim 6, wherein the second buffer layer comprises about 20 wt % to about 25 wt % sulfur in Zn (O, S).

8. The solar cell according to claim 4, wherein a thickness of the first buffer layer and a thickness of the second buffer layer are different from each other.

9. The solar cell according to claim 8, wherein the thickness of the first buffer layer is formed to be larger than the thickness of the second buffer layer.

10. The solar cell according to claim 8, wherein the thickness of the first buffer layer is formed in a thickness of 20 nm to 30 nm, and
the thickness of the second buffer layer is formed in a thickness of 10 nm to 20 nm.

11. The solar cell according to claim 4, wherein specific resistances of the first buffer layer and the second buffer layer are different from each other.

12. The solar cell according to claim 11, wherein the specific resistance of the second buffer layer is larger than that of the first buffer layer.

13. The solar cell according to claim 11, wherein the resistance of the first buffer layer is equal to or larger than 10⁻³Ω.

14. The solar cell according to claim 13, wherein the resistance of the second buffer layer is equal to or larger than 10⁻²Ω.

15. The solar cell according to claim 8, wherein the thickness of the buffer layer is 30 nm to 50 nm.

16. The solar cell according to claim 4, wherein the first buffer layer and the second buffer layer have a band gap of 2.7 eV to 2.8 eV.

17. The solar cell according to claim 1, wherein the rear electrode layer is spaced apart by first through holes.

18. The solar cell according to claim 1, wherein a specific resistance of the buffer layer varies according to a variation in content of the sulfur.

19. The solar cell according to claim 18, wherein the specific resistance of the buffer layer increases with an increase in content of the sulfur.

20. The solar cell according to claim 4, wherein the front electrode layer is arranged on the second buffer layer.
